(19) United States
(12) Patent Application Publication
(10) Pub. No.: US 2017/0069879 A1
(43) Pub. Date: Mar. 9, 2017

(54) APPARATUS AND METHOD OF MANUFACTURING DISPLAY APPARATUS

(71) Applicant: SAMSUNG DISPLAY CO., LTD., Yongin-si (KR)

(72) Inventor: Minho Um, Yongin-si (KR)

(21) Appl. No.: 15/170,790

(22) Filed: Jun. 1, 2016

(30) Foreign Application Priority Data
Sep. 7, 2015 (KR) 10-2015-0126451

(51) Int. Cl. H01L 51/56; H01L 27/32; G06F 3/041

(52) U.S. Cl. CPC H01L 51/56; G06F 3/041; H01L 27/323; H01L 27/3244; G06F 2203/04103; H01L 2227/323

(57) ABSTRACT

Provided are an apparatus and method of manufacturing a display apparatus. The apparatus for manufacturing the display apparatus includes a magnetic unit configured to move along a first surface of a cover window including at least one curved portion, a roller including a magnetic material, and configured to move along a surface of a panel member at a second surface of the cover window, and a driver connected to, and configured to move, at least one of the magnetic unit or the roller.

### CROSS-REFERENCE TO RELATED APPLICATION

This application claims the priority to, and the benefit of, Korean Patent Application No. 10-2015-0126451, filed on Sep. 7, 2015, in the Korean Intellectual Property Office, the disclosure of which is incorporated herein in its entirety by reference.

### BACKGROUND

1. Field

One or more exemplary embodiments relate to an apparatus for, and method of, manufacturing a display apparatus.

2. Description of the Related Art

Mobile electronic devices are widely used. Examples of mobile electronic devices include small electronic devices, such as mobile phones, and tablet personal computers (PCs), which have recently gained in popularity.

Such mobile electronic devices include a display unit to support various functions, and to provide visual information and images to users. Due to the recent trend of reducing the sizes of components for driving a display unit, the importance of a display unit in an electronic device is increasing. Also, display units are being developed such that they may be curved, folded, or bent at an angle.

### SUMMARY

A conventional panel with at least one curved portion might not be precisely attached to a cover window, or may separate from the cover window after being attached. To solve this problem, one or more exemplary embodiments provide a method and apparatus for manufacturing a display apparatus.

Additional aspects will be set forth in part in the description that follows and, in part, will be apparent from the description, or may be learned by practice of the presented embodiments.

According to one or more exemplary embodiments, an apparatus for manufacturing a display apparatus includes a magnetic unit configured to move along a first surface of a cover window including at least one curved portion, a roller including a magnetic material, and configured to move along a surface of a panel member at a second surface of the cover window, and a driver connected to, and configured to move, at least one of the magnetic unit or the roller.

The apparatus may further include a moving roller between the magnetic unit and the first surface of the cover window that is configured to be rotatably moved.

The driver may be configured to move the at least one of the magnetic unit or the roller from a portion of the cover window to a first end of the cover window.

The driver may be further configured to move the at least one of the magnetic unit or the roller from the first end of the cover window to a second end of the cover window.

The apparatus may further include a panel fixing unit spaced apart from the roller that is configured to fix both ends of the panel member.

The roller may further include an external cover surrounding the magnetic material.

The panel member may include at least one of a display panel, a touch screen panel, or a protection film.

A magnitude of magnetic force of the magnetic unit may be configured to be varied according to a curvature of the cover window.

The cover window may include a first cover window that is flat, and a second cover window that extends from the first cover window and is curved.

The magnitude of the magnetic force of the magnetic unit may be configured to be greater when the magnetic unit is adjacent the second cover window than when the magnetic unit is adjacent the first cover window.

The apparatus may further include a jig that is configured to accommodate the cover window, and that includes a shape corresponding to the first surface of the cover window, and the magnetic unit may be configured to move along the surface of the jig.

According to one or more exemplary embodiments, a method of manufacturing a display apparatus includes arranging a magnetic unit on a cover window, arranging a panel member on a surface of the cover window, arranging a roller to correspond to the magnetic unit, and attaching the cover window and the panel member to each other by moving at least one of the magnetic unit or the roller.

The method may further include applying an adhesive on at least one of the cover window or the panel member.

The attaching the cover window and the panel member to each other may include moving at least one of the magnetic unit or the roller from a portion of the cover window to a first end of the cover window.

The attaching the cover window and the panel member to each other further may include moving at least one of the magnetic unit or the roller from the first end of the cover window to a second end of the cover window.

The method may further include fixing both ends of the panel member on a panel fixing unit, and maintaining tension of the panel member.

The attaching the cover window and the panel member to each other may be performed in a vacuum state.

The method may further include arranging an adhesive between the cover window and the panel member.

A magnitude of magnetic force of the magnetic unit may be configured to vary according to a curvature of the cover window.

The panel member may include at least one of a display panel, a touch screen, or a protection film.

### BRIEF DESCRIPTION OF THE DRAWINGS

These and/or other aspects will become apparent and more readily appreciated from the following description of the exemplary embodiments, taken in conjunction with the accompanying drawings, in which:

FIG. 1 is a cross-sectional view of an apparatus for manufacturing a display apparatus, according to an exemplary embodiment;

FIG. 2 is a schematic sectional view of the display apparatus manufactured by the manufacturing apparatus of FIG. 1;

FIG. 3 is a schematic plan view of a display panel in the display apparatus of FIG. 1;

FIG. 4 is a cross-sectional view of the display panel cut along the line IV-IV of FIG. 3; and

FIG. 5 is a schematic sectional view of an apparatus for manufacturing a display apparatus, according to another exemplary embodiment.

### DETAILED DESCRIPTION

Features of the inventive concept and methods of accomplishing the same may be understood more readily by reference to the following detailed description of embodiments and the accompanying drawings. The inventive concept may, however, be embodied in many different forms and should not be construed as being limited to the embodiments set forth herein. Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof will not be repeated. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element, layer, region, or component is referred to as being “on,” “connected to,” or “coupled to” another element, layer, region, or component, it can be directly on, connected to, or coupled to the other element, layer, region, or component, or one or more intervening elements, layers, regions, or components may be present. In addition, it will also be understood that when an element or layer is referred to as being “between” two elements or layers, it can be the only element or layer between the two elements or layers, or one or more intervening elements or layers may also be present.

In the following examples, the x-axis, the y-axis and the z-axis are not limited to three axes of a rectangular coordinate system, and may be interpreted in a broader sense. For example, the x-axis, the y-axis, and the z-axis may be perpendicular to one another, or may represent different directions that are not perpendicular to one another.

The terminology used herein is for the purpose of describing particular embodiments only and is not intended to be limiting of the present invention. As used herein, the singular forms “a,” “an,” and “the” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

When a certain embodiment may be implemented differently, a specific process order may be performed differently from the described order. For example, two consecutively described processes may be performed substantially at the same time or performed in an order opposite to the described order.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

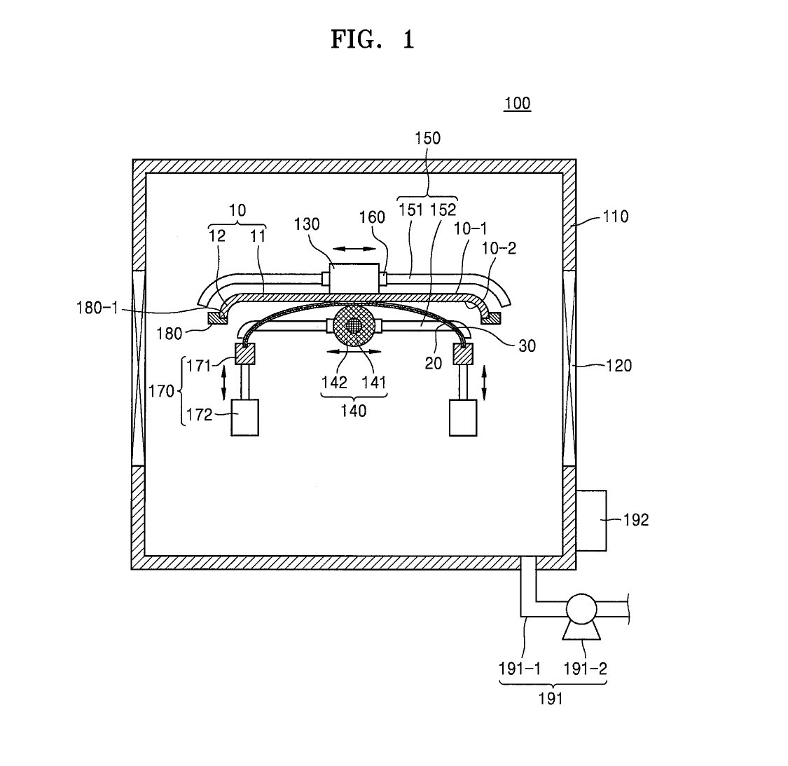

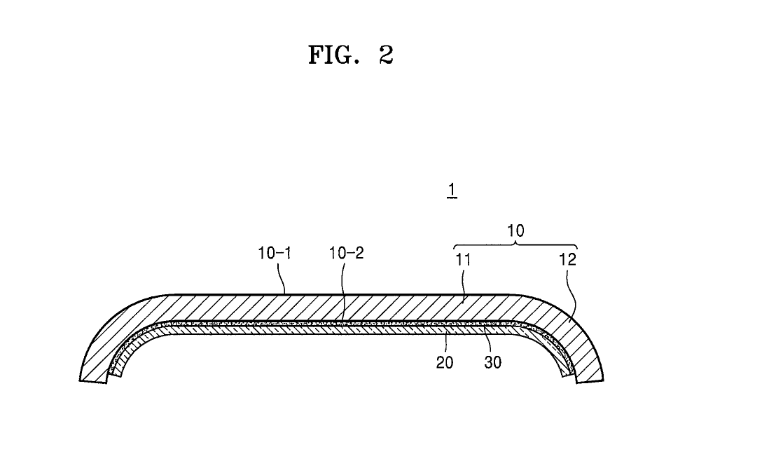

FIG. 1 is a cross-sectional view of an apparatus 100 for manufacturing a display apparatus, according to an exemplary embodiment, and FIG. 2 is a schematic sectional view of the display apparatus manufactured by the apparatus 100 of FIG. 1.

Referring to FIGS. 1 and 2, the apparatus 100 may include a chamber 110, a magnetic unit 130, a roller 140, a guide unit 150, a driver 160, a panel fixing unit 170, an accommodation unit 180, a pressure adjusting unit 191, and a controller 192.

The chamber 110 may have an inner space, and a portion of the chamber 110 may be open (e.g., may be able to be opened or closed). A gate valve 120 may be provided in the open portion of the chamber 110 so that the open portion of the chamber 110 may be selectively opened or closed.

The magnetic unit 130 may generate magnetic force. The magnetic unit 130 may include a permanent magnet. According to the present embodiment, the magnetic unit 130 may include an electromagnet having an adjustable magnetic force. Hereinafter, an example in which the magnetic unit 130 includes an electromagnet will be described for convenience.

The roller 140 may face the magnetic unit 130. The roller 140 may apply force (e.g., mechanical force) toward the magnetic unit 130 due to the magnetic force (e.g., an attractive magnetic force) of the magnetic unit 130. The roller 140 may include a core 141 that includes a magnetic material (such as metal), and may include an external cover 142 that surrounds an external surface of the core 141. The external cover 142 may include an elastic material, such as urethane, silicone, and rubber. The external cover 142 may prevent damage to a panel member 20 when force is applied to the panel member 20.

The guide unit 150 may be provided in the chamber 110, and may guide movement of at least one of the magnetic unit 130 and the roller 140. For example, the guide unit 150 may include a first guide unit 151 for guiding movement of the magnetic unit 130, and a second guide unit 152 for guiding movement of the roller 140.

The first guide unit 151 may be formed to have a shape that identically or similarly corresponds to a first surface 10-1 of a cover window 10. That is, the first guide unit 151 may guide the magnetic unit 130 such that the magnetic unit 130 moves along the first surface 10-1 of the cover window 10. The first guide unit 151 may have various shapes. For example, the first guide unit 151 may be shaped as a rail. Alternatively, the first guide unit 151 may include a linear motion guide unit. However, the first guide unit 151 is not limited thereto, and may include any device or structure that may guide the magnetic unit 130 to follow a certain track. For convenience of description, an example in which the first guide unit 151 is shaped as a rail will be described below.

The second guide unit 152 may be formed to have a shape that identically or similarly corresponds to the first guide unit 151. The second guide unit 152 may face the first guide unit 151, and may guide the roller 140. Also, the second guide unit 152 may face a second surface 10-2 of the cover window 10, which is opposite to the first surface 10-1 of the cover window 10. That is, the second guide unit 152 may guide the roller 140 such that the roller 140 moves along the second surface 10-2 of the cover window 10. Because the second guide unit 152 is substantially the same as the first guide unit 151, detailed description of the second guide unit 152 will be omitted. For convenience of description, an example in which the second guide unit 152 is shaped as a rail will be described below.

The driver 160 may move at least one of the magnetic unit 130 and the roller 140. For convenience of description, an example in which the driver 160 moves the magnetic unit 130 will be mainly described below. The driver 160 may have various shapes. For example, according to an exemplary embodiment, the driver 160 may include a linear motor that is installed in the first guide unit 151, and that moves the first guide unit 151. According to another exemplary embodiment, the driver 160 may include a motor and a first gear unit that is connected to the motor. The first guide unit 151 may include a second gear unit that engages with the first gear unit of the driver 160, and that moves the first gear unit. The first and second gear units may have various shapes. For example, the first gear unit may include a pinion gear, and the second gear unit may include a rack gear. The pinion gear may engage and move with the rack gear. The first gear unit may rotate according to motion of the motor, and may move along a surface of the second gear unit. According to another exemplary embodiment, the first gear unit may include a pinion gear, and the second gear unit may include a worm gear. According to another exemplary embodiment, the driver 160 may include a motor, and may also include a sliding unit that is installed in the magnetic unit 130. In this case, the first guide unit 151 may include a ball screw. The magnetic unit 130 may move by operating the motor to rotate the ball screw, which thus causes the sliding unit to linearly move along the ball screw.

The driver 160 is not limited to the description above, and may include all devices that may move the magnetic unit 130. For convenience of description, an example in which the driver 160 includes a linear motor that moves the magnetic unit 130 along the first guide unit 151 will be described below.

The panel fixing unit 170 may fix the panel member 20. A pair of panel fixing units 170 may be installed in the chamber 110. The pair of panel fixing units 170 may face one another, and may fix ends of the panel member 20. The panel fixing unit 170 may include a fixing unit 171, or a pair of fixing units 171, that fixes both ends of the panel member 20, and a position changing unit 172 that is connected with each fixing unit 171, and that is configured to change a position of the fixing unit 171. The fixing unit 171 may include a clamp, and may fix an end of the panel member 20. Also, the position changing unit 172 may have various shapes. For example, the position changing unit 172 may include a cylinder that is connected with the fixing unit 171.

According to another exemplary embodiment, the position changing unit 172 may include a linear motor that is connected with the fixing unit 171, and a panel fixing unit guide that guides the linear motor. According to another exemplary embodiment, the position changing unit 172 may include a moving block on which the fixing unit 171 is provided, a ball screw that moves the moving block, and a motor that is connected with the ball screw. According to another exemplary embodiment, the position changing unit 172 may include a linear motion guide on which the fixing unit 171 is provided, a motor that is connected with the fixing unit 171 and that moves the fixing unit 171, and a gear unit. However, the position changing unit 172 is not limited to the description above. The position changing unit 172 may include any device and structure that may be connected with the fixing unit 171, and may linearly move the fixing unit 171. For convenience of description, an example in which the fixing unit 171 includes a cylinder will be described below.

The accommodation unit 180 may be formed to accommodate the cover window 10. The accommodation unit 180 may support boundaries of the cover window 10. In particular, the accommodation unit 180 may be quadrilateral-shaped, may have a hole in the center, and may support all boundaries of (e.g., a perimeter of) the cover window 10. According to another exemplary embodiment, the accommodation unit 180 may be bar-shaped, and may support a portion of the boundaries of the cover window 10. For convenience of description, an example in which the accommodation unit 180 is bar-shaped and supports a portion of the boundaries of (e.g., the perimeter of) the cover window 10 will be mainly described below.

The accommodation unit 180 may include a hole 180-1 that accommodates a portion of the boundaries of the cover window 10. The hole 180-1 may be stair-shaped so that the cover window 10 is not misaligned.

The pressure adjusting unit 191 may include a connection pipe 191-1 that is connected with the chamber 110, and a pump 191-2 that is installed in the connection pipe 191-1. In this case, the pressure adjusting unit 191 may maintain air pressure, or may maintain a vacuum state, in the chamber 110.

The controller 192 may be installed inside or outside of the apparatus 100. In this case, the controller 192 may have various forms. For example, the controller 192 may include a computer(s), such as a personal computer or a laptop computer. Alternatively, the controller 192 may be a circuit board that is installed in the chamber 110. Alternatively, the controller 192 may include a mobile terminal, such as a mobile device or a personal digital assistant (PDA). However, the controller 192 is not limited thereto, and may include any device or structure that controls operations of components in the apparatus 100 via a preset program. For convenience of description, an example in which the controller 192 is provided as a circuit board at an outer wall of the chamber 110 will be described below.

With regard to operations of the apparatus 100, the panel member 20 and the cover window 10 may be manufactured and inserted into the chamber 110. The panel member 20 and the cover window 10 may be moved from the outside of the chamber 110 into the chamber 110 by using various methods. According to an exemplary embodiment, the panel member 20 and the cover window 10 may be moved into the chamber 110 by using a robotic arm. According to another exemplary embodiment, the panel member 20 and the cover window 10 may be moved into the chamber 110 via a shuttle.

The cover window 10 may have at least one curved portion, and may include various light-transmitting materials. For example, the cover window 10 may include acryl or plastic. According to another exemplary embodiment, the cover window 10 may include a glass material. The cover window 10 may include a plurality of layers by using a transparent material. For convenience of description, an example in which the cover window 10 includes a glass material will be described below.

The cover window 10 may include a first cover window 11 and a second cover window 12. In this case, the first cover window 11 may be flat, and the second cover window 12 may extend from the first cover window 11 and be curved. In particular, the second cover window 12 may be curved, as a curved surface with a certain curvature.

The panel member 20 may include various devices. For example, the panel member 20 may include a display panel. According to another exemplary embodiment, the panel member 20 may include a touch screen panel (TSP). According to another exemplary embodiment, the panel member 20 may include a protection film that is attached onto the cover window 10. The protection film may prevent the cover window 10 from scratches or impurities. However, the panel member 20 is not limited thereto, and the panel member 20 may include any type of flexible devices in the field of displays, and may be attached to the cover window 10.

For convenience of description, an example in which the panel member 20 includes a display panel will be described below.

An adhesive 30 may be provided on at least one of the panel member 20 and the cover window 10. The adhesive 30 may be provided on a surface of the panel member 20, or on a surface of the cover window 10. The surface of the panel member 20 may face the surface of the cover window 10. The adhesive 30 may include an optical adhesive, such as an optical clearance adhesive (OCA).

After the cover window 10 and the panel member 20 are inserted into the chamber 110, the adhesive 30 may be provided on at least one of the cover window 10 and the panel member 20. According to another exemplary embodiment, the adhesive 30 may be provided on at least one of the cover window 10 and the panel member 20, and then the cover window 10 and the panel member 20 may be inserted into the chamber 110. For convenience of description, an example in which the adhesive 30 is provided on the panel member 20 before the cover window 10 and the panel member 20 are inserted into the chamber 110 will be described below.

When the panel member 20 and the cover window 10 are inserted into the chamber 110, the driver 160 may move the magnetic unit 130 from the center of the cover window 10 to an end of the cover window 10 along the first surface 10-1 of the cover window 10. In the roller 140, the core 141 may move with respect to a surface of the panel member 20 due to the magnetic force of the magnetic unit 130. In particular, because of the magnetic force of the magnetic unit 130, the roller 140 may apply force to the panel member 20 toward the cover window 10. Due to such force, the panel member 20 and the cover window 10 may be coupled to each other.

In the case above, the magnetic unit 130 and the roller 140 may be bar-shaped. The widths or lengths of the magnetic unit 130 and the roller 140 (e.g., the structures along which the magnetic unit 130 and the roller 140 respectively move) may be substantially the same as those of the cover window 10.

The driver 160 may move the magnetic unit 130 from the center of the cover window 10 to an end (e.g., a first end) of the cover window 10, and may then move the magnetic unit 130 from the end of the cover window 10 to the other end (e.g., a second end) of the cover window 10. In this case, the roller 140 may move with the magnetic unit 130 along a surface of the panel member 20, from the end of the cover window 10 to the other end of the cover window 10.

When the driver 160 is moving the magnetic unit 130, the panel fixing unit 170 may adjust heights of both ends of the panel member 20. In this case, the panel fixing unit 170 may be controlled by the controller 192 such that respective positions of both ends of the panel member 20 correspond to preset positions according to a position of the magnetic unit 130, so as to maintain tension of the panel member 20 constant.

Also, while the above-described operations are performed, when the magnetic unit 130 is located at a curved portion of the cover window 10 (e.g., at the end of the cover window 10, at the other end of the cover window 10, or at the second cover window 12), the controller 192 may adjust the magnetic force of the magnetic unit 130. For example, when the magnetic unit 130 reaches the curved portion of the cover window 10 (or reaches the second cover window 12), the controller 192 may control the magnetic unit 130 such that the magnetic force of the magnetic unit 130 at the curved portion of the cover window 10 (or the second cover window 12) is greater than the magnetic force of the magnetic unit 130 at a flat portion of the cover window 10 (e.g., at the center of the cover window 10, or at the first cover window 11). The controller 192 may adjust the magnetic force by adjusting current of an electromagnet of the magnetic unit 130.

When the magnetic force of the magnetic unit 130 is adjusted as described above, it is possible to prevent separation between the cover window 10 and the panel member 20 at the curved portion of the cover window 10 (or at the second cover window 12) due to restoring force of the panel member 20. That is, when the panel member 20 is attached to the curved portion of the cover window 10 (or to the second cover window 12), the panel member 20 may separate from the cover window 10 due to the restoring force of the panel member 20. Then, as described above, the magnetic force of the magnetic unit 130 may be increased so that greater force is applied to the panel member 20 toward the cover window 10. Accordingly, the panel member 20 may be completely attached to the curved portion of the cover window 10 (or to the second cover window 12), and may thus be prevented from being separated from the cover window 10.

When the processes above are finished, the cover window 10, on which the panel member 20 is attached, may be removed from the chamber 110.

While the processes above are being performed, the controller 192 may adjust air pressure inside the chamber 110 by using the pump 191-2. That is, when the cover window 10 and the panel member 20 are inserted into the chamber 110, the controller 192 may control the pump 191-2 such that the pressure inside the chamber 110 is substantially the same as the ambient air pressure. Alternatively, while the cover window 10 and the panel member 20 are being attached to one another, the controller 192 may adjust the pressure inside the chamber 110 to be substantially the same as a vacuum state.

Therefore, according to the apparatus 100 and the above-described manufacturing method, the panel member 20 may be accurately and strongly attached onto the curved cover window 10. Also, according to the apparatus 100 and the above-described manufacturing method, the curved cover window 10 may be conveniently and quickly attached to the panel member 20.

Hereinafter, the panel member (e.g., the display panel) 20, will be described below.

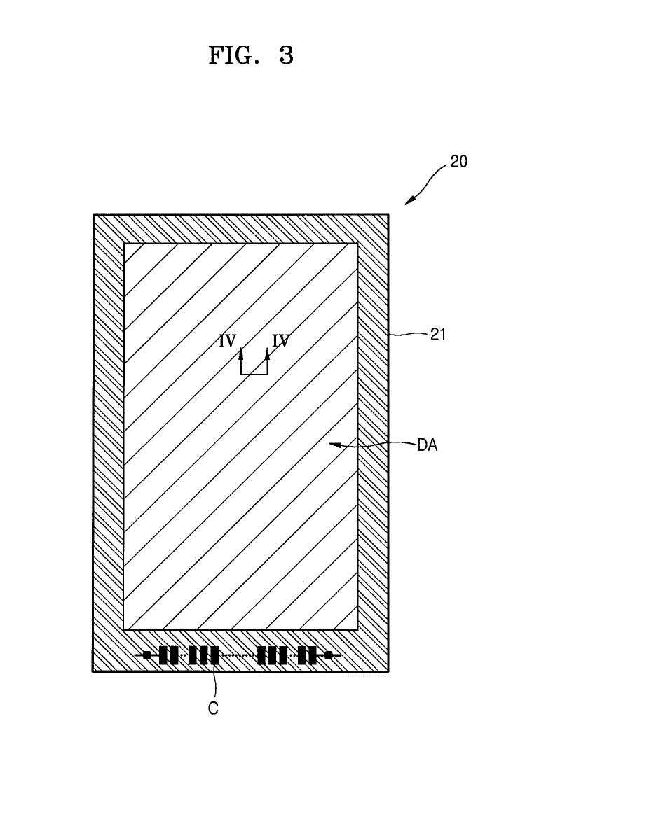

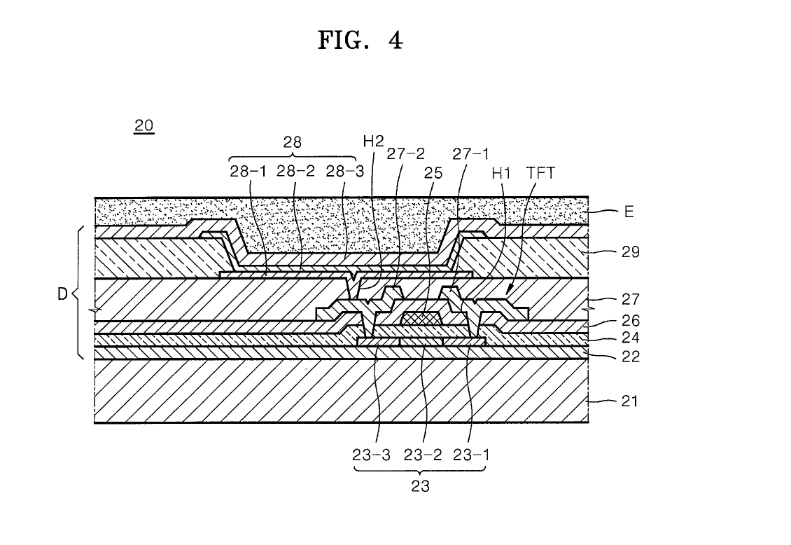

FIG. 3 is a schematic plan view of the display panel 20 in the display apparatus of FIG. 1, and FIG. 4 is a cross-sectional view of the display panel 20 cut along the line IV-IV of FIG. 3.

Referring to FIGS. 3 and 4, the display panel 20 may include a substrate 21, on which a display area DA and a non-display area are defined. The non-display area may be defined on boundaries of the display area DA (e.g., may surround the display area DA). An emission unit D is provided in the display area DA, and power wires may be provided in the non-display area. Also, a pad unit C may be provided in the non-display area.

The display panel 20 may include the substrate 21 and the emission unit D. Also, when the display panel 20 is an organic light-emitting display panel, the display panel 20 may include a thin film encapsulating layer E on the emission unit D. The substrate 21 may include a plastic material, or a metallic material, such as stainless steel (SUS) or titanium (Ti). Alternatively, the substrate 21 may include polyimide (PI). For convenience of description, an example in which the substrate 21 includes PI will be described below.

The emission unit D may be formed on the substrate 21. The emission unit D may include a thin film transistor TFT, a passivation layer 27 covering the thin film transistor TFT, and an organic light-emitting device (OLED) 28 on the passivation layer 27.

In this case, the substrate 21 may include a glass material, although the present invention is not limited thereto. The substrate 21 may include a plastic material, or a metallic material, such as SUS or Ti. Alternatively, the substrate 21 may include PI. For convenience of description, an example in which the substrate 21 includes PI will be described below.

A buffer layer 22 may be formed on the substrate 21 by using an organic compound and/or an inorganic compound, for example, SiO_{x(x≦1)} or SiN_{x(x≧1)}.

After an active layer 23 is arranged with a predetermined pattern on the buffer layer 22, the active layer 23 is covered by a gate insulating layer 24. The active layer 23 includes a source area 23-1 and a drain area 23-3, and also includes a channel area 23-2 between the source area 23-1 and the drain area 23-3.

The active layer 23 may include various materials. For example, the active layer 23 may include an inorganic semiconductor material, such as amorphous silicon or crystalline silicon. As another example, the active layer 23 may include an oxide semiconductor material, or alternatively, an organic semiconductor material. For convenience of description, an example in which the active layer 23 includes amorphous silicon will be described below.

The active layer 23 is formed by forming an amorphous silicon layer on the buffer layer 22, by crystallizing the amorphous silicon layer into a polycrystalline silicon layer, and by patterning the polycrystalline silicon layer. The source area 23-1 and the drain area 23-3 of the active layer 23 are doped with impurities depending on a type of the thin film transistor TFT, for example, depending on whether the transistor is a driving thin film transistor or a switching thin film transistor.

A gate electrode 25 that corresponds to the active layer 23, and the interlayer insulating layer 26 that covers the gate electrode 25, are formed on the gate insulating layer 24.

After forming a contact hole (e.g., a pair of contact holes) H1 in the interlayer insulating layer 26 and in the gate insulating layer 24, a source electrode 27-1 and a drain electrode 27-2 are formed on the interlayer insulating layer 26 such that the source electrode 27-1 and the drain electrode 27-2 respectively contact the source area 23-1 and the drain area 23-3 of the active layer 23.

The passivation layer 27 is formed on the thin film transistor TFT that is formed as described above. A pixel electrode 28-1 of the OLED 28 is formed on the passivation layer 27. The pixel electrode 28-1 contacts the drain electrode 27-2 of the thin film transistor TFT via a via hole H2 formed in the passivation layer 27. The passivation layer 27 may include a single layer, or may include a plurality of layers that are formed using an inorganic material and/or an organic material. The passivation layer 27 may include a planarizing layer so that a surface thereof may be substantially flat regardless of curves under the surface, or may be formed according to the curves under the surface thereof. Also, the passivation layer 27 may include a transparent insulating layer to obtain a resonance effect.

After the pixel electrode 28-1 is formed on the passivation layer 27, a pixel-defining layer 29 includes an organic material and/or an inorganic material to cover the pixel electrode 28-1 and the passivation layer 27, and is opened (e.g., etched) to expose the pixel electrode 28-1.

Also, an intermediate layer 28-2 and an opposite layer 28-3 are formed on at least the pixel electrode 28-1.

The pixel electrode 28-1 functions as an anode electrode, and the opposite layer 28-3 functions as a cathode electrode, or vice versa.

The intermediate layer 28-2 insulates the pixel electrode 28-1 from the opposite layer 28-3. An organic emission layer emits light by applying voltages with different polarities to the intermediate layer 28-2.

The intermediate layer 28-2 may include an organic emission layer. In another example, the intermediate layer 28-2 may include an organic emission layer, and may further include at least one of a hole injection layer (HIL), a hole transport layer (HTL), an electron transport layer (ETL), and an electron injection layer (EIL). However, the present embodiment is not limited thereto, and the intermediate layer 28-2 may include an organic emission layer and may further include other various functional layers.

A unit pixel includes a plurality of sub-pixels that may emit various colors of light. For example, the plurality of sub-pixels may respectively emit red, green, and blue light, or may respectively emit red, green, blue, and white light.

The thin film encapsulating layer E may include a plurality of inorganic layers, or may include an inorganic layer and an organic layer.

The organic layer of the thin film encapsulation layer E includes a polymer, and may be a single layer or a stack of layers formed of any one of polyethylene terephthalate, polyimide, polycarbonate, epoxy, polyethylene, and polyacrylate. The organic layer may include polyacrylate, and in detail, may include a polymerized monomer composition including diacrylate-based monomer and triacrylate-based monomer. The monomer composition may further include monoacrylate-based monomer. Also, the monomer composition may further include a well-known photoinitiator, such as trimethyl benzoyl diphenyl phosphine oxide (TPO), but embodiments of the present invention are not limited thereto.

The inorganic layer of the thin film encapsulation layer E may be a single layer, or may be a stack of layers including a metal oxide or a metal nitride. For example, the inorganic layer may include any one of SiNx, Al₂O₃, SiO₂, and TiO₂.

The top layer of the thin film encapsulation layer E that is exposed to the outside may include an inorganic layer to reduce or prevent intrusion of moisture into the OLED 28.

The thin film encapsulation layer E may include at least one sandwich structure, in which at least one organic layer is inserted between at least two inorganic layers. As another example, the thin film encapsulation layer E may include at least one sandwich structure in which at least one inorganic layer is inserted between at least two organic layers. As another example, the thin film encapsulation layer E may include a sandwich structure in which at least one organic layer is inserted between at least two inorganic layers, and may include a sandwich structure in which at least one inorganic layer is inserted between at least two organic layers. The thin film encapsulation layer E may include a first inorganic layer, a first organic layer, and a second inorganic layer sequentially formed from the top portion of the OLED 28.

As another example, the thin film encapsulation layer 130 may include a first inorganic layer, a first organic layer, a second inorganic layer, a second organic layer, and a third inorganic layer sequentially formed from the top portion of the OLED 28.

As another example, the thin film encapsulation layer E may include a first inorganic layer, a first organic layer, a second inorganic layer, a second organic layer, a third inorganic layer, a third organic layer, and a fourth inorganic layer, which are sequentially formed from the top portion of the OLED 28.

A halogenized metal layer including lithium fluoride (LiF) may be additionally included between the OLED 28 and the first inorganic layer. The halogenized metal layer may reduce the likelihood of the OLED being damaged during the formation of the first inorganic layer by a sputtering method or by a plasma deposition method.

The first organic layer may be smaller than the second inorganic layer, and the second organic layer may be smaller than the third inorganic layer.

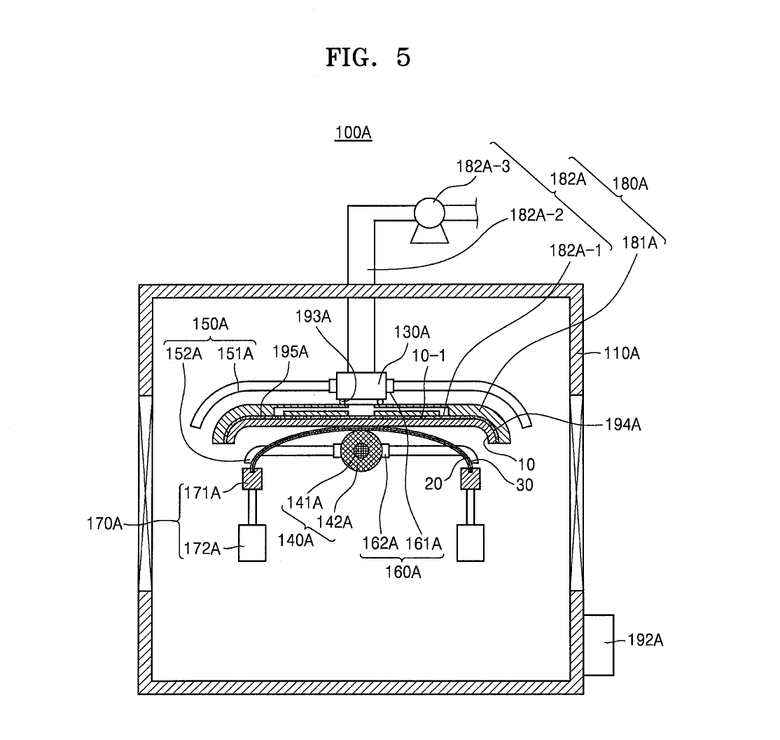

FIG. 5 is a schematic sectional view of an apparatus 100A for manufacturing a display apparatus, according to another exemplary embodiment.

Referring to FIG. 5, the apparatus 100A may include a chamber 110A, a magnetic unit 130A, a roller 140A, a guide unit 150A, a driver 160A, a panel fixing unit 170A, an accommodation unit 180A, and a controller 192A. The chamber 110A, the magnetic unit 130A, the roller 140A, the guide unit 150A, the panel fixing unit 170A, and the controller 192A are the same as, or are similar to, the corresponding components described with reference to FIGS. 1 and 2, and thus, repeated detailed description thereof will be omitted.

The driver 160A may include a first driver 161A provided in the magnetic unit 130A, and a second driver 162A provided in the roller 140A. The first driver 161A and the second driver 162A may be synchronized, and may move simultaneously/concurrently. The first and second drivers 161A and 162A may be the same as, or may be similar to, the driver 160 described with reference to FIGS. 1 and 2, and thus, detailed description thereof will be omitted.

The accommodation unit 180A may include an accommodation jig 181A and a fixing unit 182A. The curved cover window 10 may be accommodated in the accommodation jig 181A. The accommodation jig 181A may be formed identically to, or may be formed similarly to, the cover window 10. In particular, a surface of the accommodation jig 181A may correspond to the first surface 10-1 of the cover window 10. For example, at least one portion of a surface of the accommodation jig 181A may be curved identically to, or may be curved similarly to, the first surface 10-1 of the cover window 10.

The fixing unit 182A may be provided in the accommodation jig 181A. The fixing unit 182A may have various shapes. For example, the fixing unit 182A may include, or may be comprised of, a protrusion at a surface of the accommodation jig 181A. When the fixing unit 182A is formed as a protrusion, the fixing unit 182A may protrude from a surface of the accommodation jig 181A on which the cover window 10 is accommodated, and a portion of the fixing unit 182A may be bent to hang or support an end of the cover window 10. According to another exemplary embodiment, the fixing unit 182A may include an adhesive film. According to another exemplary embodiment, the fixing unit 182A may include an electrostatic chuck. When the fixing unit 182A is formed as an adhesive film or as an electrostatic chuck, the fixing unit 182A may be provided at a surface of the accommodation jig 181A on which the cover window 10 is accommodated. According to another exemplary embodiment, the cover window 10 may be attached to the fixing unit 182A by suction. For example, the fixing unit 182A may include a passage 182A-1 provided in the accommodation unit 180A, or provided in the accommodation jig 181A, a suction pipe 182A-2 connected with the passage 182A-1, and a suction pump 182A-3 provided in, or connected to, the suction pipe 182A-2. However, the fixing unit 182A is not limited thereto, and the fixing unit 182A may include any device or structure that is configured to fix the cover window 10 to the accommodation jig 181A for attaching the cover window 10 and the panel member 20. For convenience of description, an example in which the fixing unit 182A includes the passage 182A-1, the suction pipe 182A-2, and the suction pump 182A-3 will be described below.

The apparatus 100A may include a moving roller 193A on the magnetic unit 130A. The moving roller 193A may be provided between the magnetic unit 130A and a surface of the accommodation jig 181A. The moving roller 193A may contact, and move along the surface of, the accommodation jig 181A. The moving roller 193A may reduce friction between the accommodation jig 181A and the magnetic unit 130 when the magnetic unit 130 is moving.

In addition to being in contact with the surface of the accommodation jig 181A, the moving roller 193A may contact and move along the first surface 10-1 of the cover window 10. That is, when the accommodation unit 180A is formed such that the cover window 10 is supported, as shown in FIGS. 1 and 2, the magnetic unit 130A may contact and move along the first surface 10-1 of the cover window 10. Alternatively, when the moving roller 193A is not provided, the magnetic unit 130A may move along a surface of the accommodation jig 181A. For convenience of description, an example in which the magnetic unit 130A includes the moving roller 193A, and in which the moving roller 193A contacts and moves along the first surface 10-1 of the cover window 10, will be described below.

The apparatus 100A may further include a cushion 194A on the accommodation unit 180A. The cushion 194A may be provided between the fixing unit 182A and the cover window 10. The cushion 194A may include an elastic material such as rubber, silicon, or urethane.

Operations of the apparatus 100A may be the same as, or similar to, the operations of the apparatus 100. For example, the cover window 10 and the panel member 20 may be inserted into the chamber 110A. The technology of inserting the cover window 10 and the panel member 20 into the chamber 110A has been described above, and thus, detailed description will not be repeated hereafter. Also, the adhesive 30 may be applied to at least one of the cover window 10 and the panel member 20.

The cover window 10 may be accommodated on the accommodation jig 181A, and may then be fixed by the fixing unit 182A. That is, the cover window 10 may be fixed on the accommodation jig 181A by operating the suction pump 182A-3 to discharge air inside the passage 182A-1 and inside the suction pipe 182A-2 to the outside, such that the inside of the passage 182A-1 and the suction pipe 182A-2 is similar to a vacuum state. In this case, air pressure in the chamber 110A may be maintained.

Also, the panel member 20 may be fixed to the panel fixing unit 170A. The panel fixing unit 170A may fix both ends of the panel member 20.

After the cover window 10 is accommodated on the accommodation jig 181A, the first driver 161A may move the magnetic unit 130A along a surface of the accommodation jig 181A. The magnetic unit 130A may move along a first guide unit 151A.

The controller 192A may control the first driver 161A such that the magnetic unit 130A is moved from the center of the accommodation jig 181A to an end of the accommodation jig 181A, and is then moved to the other end of the accommodation jig 181A. In this case, the controller 192A may control the second driver 162A to move at the same speed as the first driver 161A. Due to the operation of the second driver 162A, the roller 140A may move along a second guide unit 152A in accordance with the movement of the magnetic unit 130A. In particular, the roller 140A may apply force to the panel member 20 by sequentially moving from the center of the cover window 10 to an end of the cover window 10, and then moving from the end of the cover window 10 to the other end of the cover window 10. Then, a core 141A may be attracted toward the magnetic unit 130A due to the magnetic force of the magnetic unit 130A.

Also, an external cover 142A may contact, and may prevent damage of, a surface of the panel member 20.

In the case above, the controller 192A may adjust the magnetic force of the magnetic unit 130A to be substantially the same as, and in a manner similar to, that described in FIGS. 1 and 2. Also, the controller 192A may control the panel fixing unit 170A, and may adjust both ends of the panel member 20 to maintain tension of the panel member 20 constant. That is, a fixing unit 171A may fix both ends of the panel member 20, and a position changing unit 172A may change a position of the fixing unit 171A based on respective positions of the magnetic unit 130A and the roller 140A.

After the panel member 20 is attached to the cover window 10, the cover window 10, on which the panel member 20 is attached, may be removed from the chamber 110A.

Therefore, according to the apparatus 100A and the above-described manufacturing method, the panel member 20 may be accurately and strongly attached to the curved cover window 10.

Also, according to the apparatus 100A and the above-described manufacturing method, the curved cover window 10 may be conveniently and quickly attached onto the panel member 20.

According to the apparatus 100A and the above-described manufacturing method, when the magnetic unit 130A is moving along the first surface 10-1 of the cover window 10, the moving roller 193A may contact the first surface 10-1 of the cover window 10 so that the first surface 10-1 of the cover window 10 is less damaged.

Also, according to the apparatus 100A and the above-described manufacturing method, defects caused by separation of the panel member 20 and the cover window 10 may be reduced or prevented.

While one or more exemplary embodiments have been described with reference to the figures, it will be understood by those of ordinary skill in the art that various changes in form and details may be made therein without departing from the spirit and scope as defined by the following claims and their equivalents.

What is claimed is:

1. An apparatus for manufacturing a display apparatus, the apparatus comprising:
a magnetic unit configured to move along a first surface of a cover window comprising at least one curved portion;
a roller comprising a magnetic material, and configured to move along a surface of a panel member at a second surface of the cover window; and
a driver connected to, and configured to move, at least one of the magnetic unit or the roller.

2. The apparatus of claim 1, further comprising a moving roller between the magnetic unit and the first surface of the cover window that is configured to be rotatably moved.

3. The apparatus of claim 1, wherein the driver is configured to move the at least one of the magnetic unit or the roller from a portion of the cover window to a first end of the cover window.

4. The apparatus of claim 3, wherein the driver is further configured to move the at least one of the magnetic unit or the roller from the first end of the cover window to a second end of the cover window.

5. The apparatus of claim 1, further comprising a panel fixing unit spaced apart from the roller that is configured to fix both ends of the panel member.

6. The apparatus of claim 1, wherein the roller further comprises an external cover surrounding the magnetic material.

7. The apparatus of claim 1, wherein the panel member comprises at least one of a display panel, a touch screen panel, or a protection film.

8. The apparatus of claim 1, wherein a magnitude of magnetic force of the magnetic unit is configured to be varied according to a curvature of the cover window.

9. The apparatus of claim 8, wherein the cover window comprises:
a first cover window that is flat; and
a second cover window that extends from the first cover window and is curved.

10. The apparatus of claim 9, wherein the magnitude of the magnetic force of the magnetic unit is configured to be greater when the magnetic unit is adjacent the second cover window than when the magnetic unit is adjacent the first cover window.

11. The apparatus of claim 1, further comprising a jig configured to accommodate the cover window, and comprising a shape corresponding to the first surface of the cover window,
wherein the magnetic unit is configured to move along the surface of the jig.

12. A method of manufacturing a display apparatus, the method comprising:
arranging a magnetic unit on a cover window;
arranging a panel member on a surface of the cover window;
arranging a roller to correspond to the magnetic unit; and
attaching the cover window and the panel member to each other by moving at least one of the magnetic unit or the roller.

13. The method of claim 12, further comprising applying an adhesive on at least one of the cover window or the panel member.

14. The method of claim 12, wherein the attaching the cover window and the panel member to each other comprises moving at least one of the magnetic unit or the roller from a portion of the cover window to a first end of the cover window.

15. The method of claim 14, wherein the attaching the cover window and the panel member to each other further comprises moving at least one of the magnetic unit or the roller from the first end of the cover window to a second end of the cover window.

16. The method of claim 12, further comprising:
fixing both ends of the panel member on a panel fixing unit; and
maintaining tension of the panel member.

17. The method of claim 12, wherein the attaching the cover window and the panel member to each other is performed in a vacuum state.

18. The method of claim 12, further comprising arranging an adhesive between the cover window and the panel member.

19. The method of claim 12, wherein a magnitude of magnetic force of the magnetic unit is configured to vary according to a curvature of the cover window.

20. The method of claim 12, wherein the panel member comprises at least one of a display panel, a touch screen, or a protection film.
